(19) United States
(12) Patent Application Publication
(10) Pub. No.: US 2007/0091675 A1
(43) Pub. Date: Apr. 26, 2007

(54) Double bias for a magnetic reader

(75) Inventors: Chunhong Hou, Savage, MN (US); Qing He, Plymouth, MN (US); Xuefei Tang, Eden Prairie, MN (US)

Correspondence Address: SEAGATE TECHNOLOGY LLC C/O WESTMAN;CHAMPLIN & KELLY, P.A., SUITE 1400, 900 SECOND AVENUE SOUTH, MINNEAPOLIS, MN, 55402-3319, US

(73) Assignee: Seagate Technology LLC, Scotts Valley, CA (US)

(21) Appl. No.: 11/254,283

(22) Filed: Oct. 20, 2005

(51) Int. Cl. G11C 11/15

(52) U.S. Cl. 365/173

(57) ABSTRACT

The present invention provides a tunneling giant magnetoresistance (TGMR) sensor. The sensor including an active region. The active region having a first bias layer. The sensor also including a passive region. The passive region has an insulating layer and a second bias layer. Furthermore, the insulating layer is positioned between the active region and the second bias layer.

### FIELD OF THE INVENTION

The present invention relates to magnetic sensors. More specifically, the present invention relates to magnetic read sensors.

### BACKGROUND OF THE INVENTION

A read sensor is located in a magnetic head and is configured to read data stored on a storage medium. One type of read sensor is the giant magnetoresistance spin valve sensor. Giant magnetoresistance sensors read data stored on mediums. More recently, tunneling giant magnetoresistance sensors are being utilized in place of giant magnetoresistance sensors. Tunneling magnetoresistance sensors include a thin insulating layer or barrier layer that separates two magnetic layers. Tunneling magnetoresistance sensors demonstrate a higher sensitivity or higher resistivity to changes in magnetic fields than giant magnetoresistance sensors.

Tunneling giant magnetoresistance sensors typically operate by applying electrical current perpendicular to the plane of its multiple layered structure. In a tunneling giant magnetoresistance sensor, an insulating layer is positioned on the side(s) of the multiple layered structure to prevent current leakage due to the perpendicular current flow through the spin tunneling barrier.

The tunneling giant magnetoresistance sensor needs to be stabilized against the formation of edge domain walls. The formation of edge domain walls results in electrical noise, which hinders recovery of data. One way to stabilize a TGMR sensor is to place permanent magnets outside of the insulating material. In theory, magnetic fields induced by the permanent magnets stabilize the TGMR sensor and prevent edge domain formation as well as provide proper biasing to the sensor.

Because of the relatively thick insulation material needed to prevent current leakage in the tunneling giant magnetoresistance sensor, the permanent magnets have to sit relatively far away from the edge of the free layer. Such a distance results in a weak magnetic field applied to the domain walls of the tunneling giant magnetoresistance sensor. The application of weak magnetic fields causes an unstable free layer and electrical noise in the magnetic head. Providing a thinner insulating material will not solve this problem because a thinner insulation material raises the risk of current leakage. Another option to stablize the free layer is to provide thick permanent magnets. Yet, this can lead to uneven shielding and a large shield-to-shield spacing that no longer meets the dimensional requirements for sensing data in high areal density mediums.

Embodiments of the present invention provide solutions to these and other problems, and offer advantages over the prior art.

### SUMMARY OF THE INVENTION

The present invention relates to a tunneling giant magnetoresistance sensor. A tunneling giant magnetoresistance sensor includes an active region having a sensor stack and a passive region. The sensor stack includes a pinned layer, a free layer and a barrier layer positioned between the pinned layer and the free layer. The sensor stack also includes a first bias layer formed on the free layer. The first bias layer induces a substantially uniform biasing field across the free layer. The passive region of the sensor includes a second bias layer formed on opposing sides of at least the free layer and an insulating layer positioned between the second bias layer and the active region. The first and second bias layers cooperate to apply both a uniform biasing across the free layer and a biasing field at opposing sides of at least the free layer.

### BRIEF DESCRIPTION OF THE DRAWINGS

FIG. 1 illustrates a simplified sectional view of a magnetic head.

FIG. 2 illustrates a magnetic field profile of a tunneling giant magnetoresistance sensor that includes a pair of biasing elements formed on opposing sides of the sensor.

FIG. 3 illustrates a magnetic field profile of a tunneling giant magnetoresistance sensor having an antiferromagnetic layer formed adjacent to a free layer of the sensor.

FIGS. 4-7 illustrate diagrammatic air bearing surface views of various embodiments of tunneling giant magnetoresistance sensors.

FIG. 8 illustrates a magnetic field profile of a tunneling giant magnetoresistance sensor including a first bias layer formed adjacent to a free layer of the sensor and a second bias layer formed on opposing sides of the sensor.

FIG. 9 illustrates a flowchart demonstrating a method of forming a tunneling giant magnetoresistance sensor.

### DETAILED DESCRIPTION OF ILLUSTRATIVE EMBODIMENTS

The present invention includes various embodiments of a novel tunneling giant magnetoresistance sensor. This type of sensor could be used in a data storage system device, such as a disc drive, a magnetoresistive random access memory (MRAM) device or any type of device that would utilize a magnetoresistive sensor.

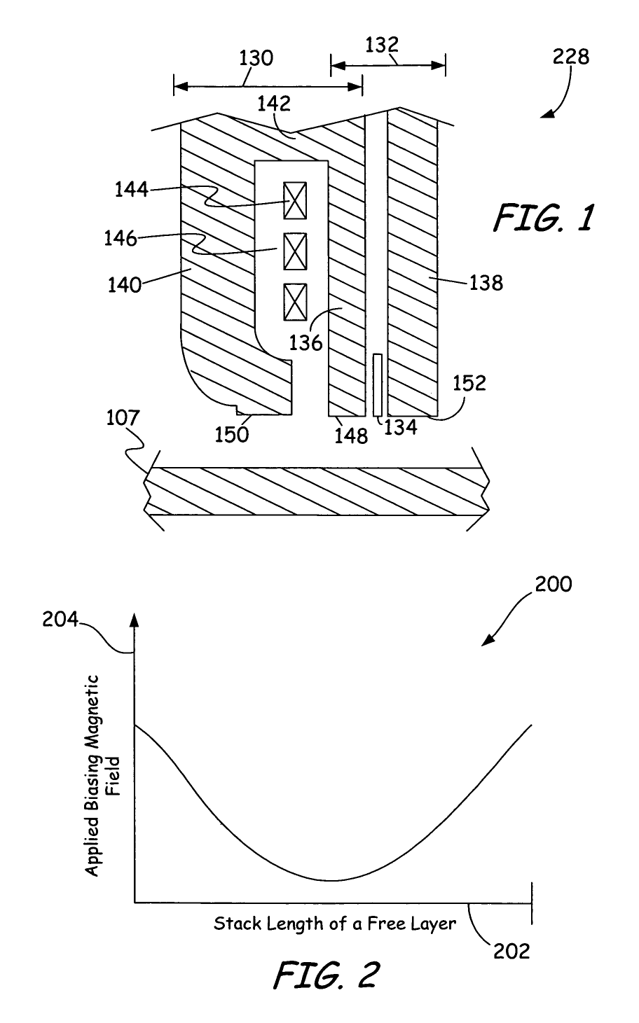

FIG. 1 is a simplified sectional view of a portion of an example magnetic head 128 and an example disc 107 that can be used in accordance with the present invention. Magnetic head 128 includes a write transducer 130 and a read transducer 132. Read transducer 132 includes a read sensor 134 that is spaced between a first pole 136, which operates as a top shield, and a bottom shield 138. The top and bottom shields 136 and 138 operate to isolate read transducer 132 from external magnetic fields that could affect sensing bits of data recorded on disc 107. Write transducer 130 includes second pole 140 and first pole 136. The first and second poles 136 and 140 are connected at back via 142. A conductive coil 144 extends between first pole 136 and second pole 140 and around back via 142. An insulating material 146 electrically insulates conductive coil 144 from first and second poles 136 and 140. First and second poles 136 and 140 include first and second pole tips 148 and 150, respectively, which face the surface of disc 107 and form a portion of an air bearing surface (ABS) 152.

Read sensor 134 can be a tunneling giant magnetoresistance sensor. Although not illustrated in detail in FIG. 1, the basic structure of a tunneling giant magnetoresistance sensor includes a stack of layers. The tunneling giant magnetoresistance sensor specifically includes an insulating layer or a barrier layer that separates two magnetic layers. One of the magnetic layers is a pinned layer. The other of the magnetic layers is a free layer. A tunneling giant magnetoresistance sensor can include an insulating material that is formed on edges of the stack of layers. In particular, the insulating material encloses the barrier layer. Since current flows perpendicularly through the plane of the layers of the tunneling giant magnetoresistance sensor, the insulating material is needed to prevent electrical current from leaking. In addition to preventing current leakage, a tunneling giant magnetoresistance sensor also needs to be stabilized against the formation of edge domain walls and needs to properly bias the free layer. In accordance with the present invention, to stabilize the tunneling giant magnetoresistance sensor and bias the free layer, a bias layer is placed outside of the insulating material and on opposing sides of at least the free layer of the stack of layers.

FIG. 2 illustrates a magnetic profile 200 of a free layer of a tunneling giant magnetoresistance sensor. The magnetic profile 200 represents a particular tunneling giant magnetoresistance sensor that includes an insulating material surrounding the sensor as well as a pair of biasing layers formed on opposing sides of the sensor and placed outside of the insulating material. The three dimensions of a tunneling giant magnetoresistance sensor include a stack height, stack length and a stripe height. The stack height and stack length are those dimensions that face an ABS, such as ABS 152 illustrated in FIG. 1. The particular dimension of the free layer represented by axis 202 is the stack length of the tunneling giant magnetoresistance sensor. Axis 204 of magnetic profile 200 represents the biasing magnetic field applied to the free layer of a tunneling giant magnetoresistance sensor by the pair of opposing biasing layers. Magnetic profile 300 illustrates that the biasing layers apply a higher magnetic field at the ends of the free layer than at the center of the free layer. The resulting application of magnetic field allows the center of the free layer to rotate while still biasing the edges of the free layer. However, the intensity of the biasing field across the free layer is not strong enough. A weak applied magnetic field causes electrical noise in the sensor.

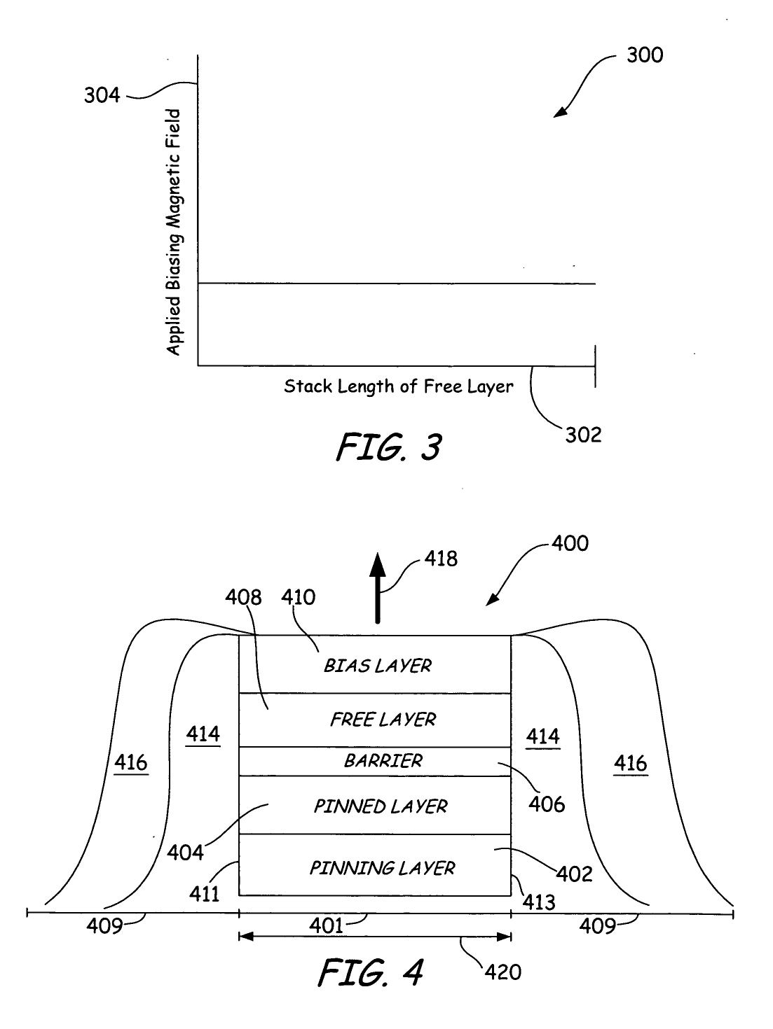

FIG. 3 illustrates a magnetic profile 300 of a free layer of a tunneling giant magnetoresistance sensor. The magnetic profile 300 that represents a particular tunneling giant magnetoresistance sensor includes an insulating material surrounding the sensor as well as an antiferromagnetic biasing layer formed adjacent the free layer. The particular dimension of the free layer represented by axis 302 is the stack length of the tunneling giant magnetoresistance sensor. Axis 304 of magnetic profile 300 represents the biasing magnetic field applied to the free layer by the bias layer formed adjacent the free layer. Magnetic profile 300 illustrates that the bias layer applies a uniform magnetic field across the stack length of the free layer. However, the uniform biasing field across the free layer is not strong enough to eliminate the domains at the edges of the free layer while still allowing the center of the free layer to rotate.

FIGS. 4-7 are diagrammatic air bearing surface (ABS) views of tunneling giant magnetoresistance sensors 400, 500, 600 and 700 in accordance with exemplary embodiments of the present invention. Some layers and components are omitted from FIGS. 4, 5, 6 and 7 to simplify the illustrations. For example, sensors 400, 500, 600 and 700 can include seed layers if desired. Furthermore, although electrical contacts or leads are not shown in FIGS. 4, 5, 6 and 7, those of skill in the art will recognize that electrical leads will be included in the sensors of the present invention.

Sensors 400, 500, 600 and 700 include active regions 401, 501, 601 and 701 and passive regions 409, 509, 609 and 709. Active regions 401, 501, 601 and 701 contain a multiple-layered sensor stack. The sensor stack includes first sides 405, 505, 605 and 705 and second sides 407, 507, 607 and 707. Passive regions 409, 509, 609 and 709 are the regions that surround the multiple layered sensor stack on first sides 411, 511, 611 and 711 and second sides 413, 513, 613 and 713.

In one embodiment, the active region 401 of sensor 400 in FIG. 4 includes a pinning layer 402, a pinned layer 404, a barrier layer 406, free layer 408 and a first bias layer 410. Pinned layer 404 is positioned on and exchange coupled with the underlying pinning layer 402. Pinned layer 404 includes a magnetic moment or magnetization direction that is substantially prevented from rotating in the presence of applied magnetic fields. Pinned layer 404 can comprise a ferromagnetic material, while pinning layer 402 can comprise an antiferromagnetic material. Example ferromagnetic materials for pinned layer 404 may include cobalt iron (CoFe), nickel iron (NiFe), a ternary alloy such as cobalt iron (CoFeX), nickel iron (NiFeX, cobalt iron boron (CoFeB), cobalt iron chromium (CoFeCr), or nickel iron cobalt (NiFeCo). Other materials having similar properties are also possible. Barrier layer 406 is positioned between pinned layer 404 and free layer 408. Free layer 408 can comprise a ferromagnetic material and is considered the “sensing” layer. Free layer 408 has a magnetization direction that is substantially free to rotate in the presence of applied magnetic fields.

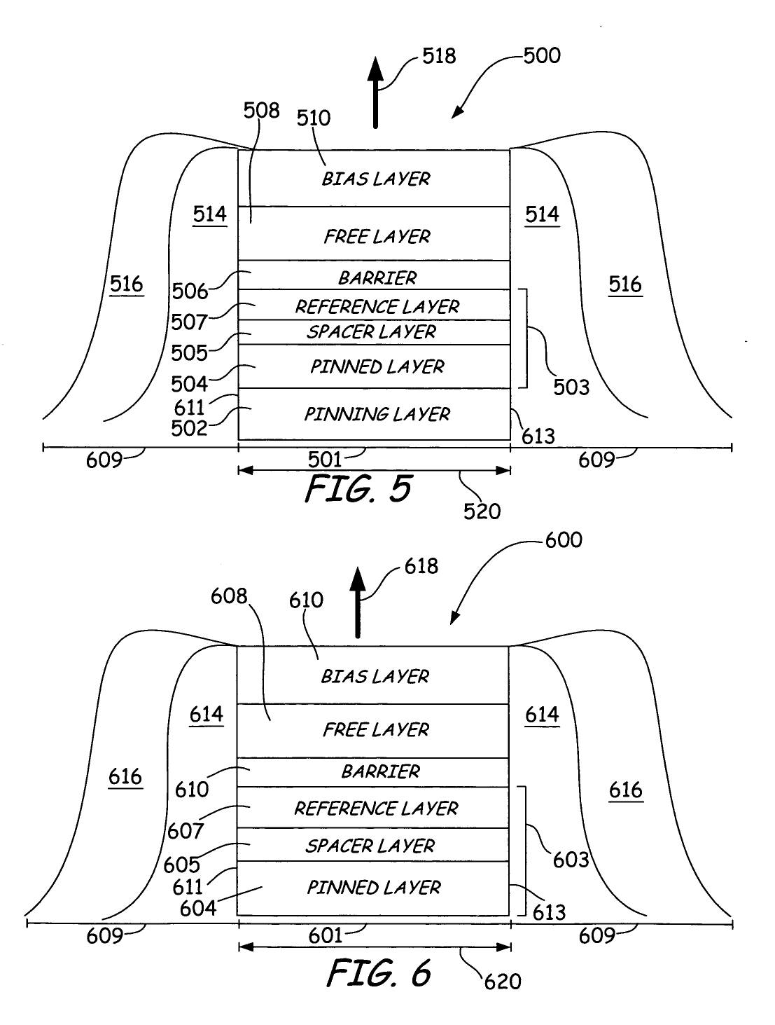

In another embodiment, the active region 501 of sensor 500 in FIG. 5 includes a pinning layer 502, a synthetic antiferromagnet (SAF) 503, a barrier layer 506, a free layer 508 and a first bias layer 510. The embodiment illustrated in FIG. 6 is similar to the embodiment illustrated in FIG. 5 in that sensor 600 includes a synthetic ferromagnet (SAF) 603, a barrier layer 606, a free layer 608 and a first bias layer 610. However, the active region 601 of sensor 600 need not have a pinning layer, such as pinning layer 502 as shown in FIG. 5. SAF 603 can provide a stiffly pinned layer 604 without the use of a pinning layer. SAFs 503 and 603 include two soft ferromagnetic layers 504, 604 and 507, 607, separated by a spacer layer 505, 605, which can be a metal such as ruthenium (Ru) or rhodium (Rh). Layer 504, 604 is often referred to as the pinned layer and is the layer in the synthetic antiferromagnet 503, 603 that can often be formed adjacent a pinning layer 502 in FIG. 5. Layer 507, 607, often referred to as the reference layer, is the layer closest to the free layer 508, 608. Reference layers 507 and 607 and pinned layers 504 and 604 of SAFs 503 and 603 include materials such as Cobalt, (Co), cobalt iron (CoFe) and cobalt nickel iron (CoNiFe). Other materials with similar properties are also possible. The exchange coupling between pinned layer 504, 604 and reference layer 507, 607 is an oscillatory function of the thickness of spacer layer 505, 605. Barrier layer 506, 606 is positioned between synthetic antiferromagnet 503, 603 and free layer 508, 608. Like sensor 400, free layers 508 and 608 of sensors 500 and 600 have magnetization that is substantially free to rotate in the presence of applied magnetic fields.

FIG. 7 illustrates a tunneling giant magnetoresistance sensor 700 in accordance with another embodiment of the present invention. The active region 701 of sensor 700 includes all of the layers of sensor 500. Those layers being a pinning layer 702, a synthetic antiferromagnet 703, a barrier layer 706, a free layer 708 and a first bias layer 710. In addition, however, the active region 701 of sensor 700 also includes a second spacer layer 712. Second spacer layer 712 is positioned between free layer 708 and first bias layer 710. Spacer layer 712 can be made of materials that are neither antiferromagnetic nor ferromagnetic materials. For example, spacer layer 712 can be made of non-magnetic materials such as copper (Cu), chromium (Cr), ruthenium (Ru) and tantalum (Ta). However, other materials with similar properties are possible. The thickness of spacer layer 712 can be adjusted to tune the bias strength applied by first bias layer 710 on free layer 708.

In accordance with the present invention, each of sensors 400, 500, 600 and 700 include active regions 401, 501, 601 and 701 having first bias layers 410, 510, 610 and 710 in combination with passive regions 409, 509, 609 and 709 having second bias layers 416, 516, 616 and 716 formed on opposing sides (i.e. first sides 411, 511, 611, 711 and second sides 413, 513, 613 and 713) of the sensor stack to bias free layers 408, 508, 608 and 708 while still allowing the free layers to rotate in response to application of magnetic fields. Free layers 508, 608, 708 and 808 can be a ferromagnetic material. Example materials may include cobalt iron (CoFe), nickel iron (NiFe), and a ternary alloy including either cobalt iron (CoFeX), nickel iron (NiFeX), cobalt iron boron (CoFeB), cobalt iron chromium (CoFeCr) or iron cobalt (NiFeCo). Free layers 408, 508, 608 and 708 can also be composed of multiple layers of different selected materials that are given as example free layer materials above. For example, a free layer can be composed of a multi-layer stack of NiFe, NiFeX, CoFe, CoFeX and NiFeCo. In addition, each passive region 409, 509, 609 and 709 of sensors 400, 500, 600 and 700 includes insulating layers 414, 514, 614 and 714. Second biasing layers 416, 516, 616 and 716 can include permanent magnets, or any material that provides a bias.

Insulating layers 414, 514, 614 and 714 are illustrated as surrounding the sensor stack or active regions of each sensor 400, 500, 600 and 700. However, insulating layers 414, 514, 614 and 714 need to at least surround barrier layer 406, 506, 606 and 706 of each sensor 400, 500, 600 and 700. Each sensor 400, 500, 600 and 700 includes a sensor current 418, 518, 618, and 718 that flows perpendicular to stack length 420, 520, 620 and 720 and through barrier layer 406, 506, 606 and 706 (one skilled in the art will appreciate that current can be applied in a direction opposite from the direction illustrated in FIGS. 4, 5, 6 and 7 without departing from the present invention). Each barrier layer 406, 506, 606 and 706 needs to be insulated by a thick enough insulation to prevent current 418, 518, 618 and 718 from leaking. An example insulating material includes aluminum oxide (Al₂O₃). However, other types of materials with similar properties are possible.

In accordance with the present invention, to properly bias and yet still allow free layers 408, 508, 608 and 708 to rotate in response to magnetic fields, first bias layers 410, 510, 610 and 710 are formed adjacent to the free layers and the second bias layers 416, 516, 616 and 716 are formed on opposing sides of at least the free layer of each sensor 400, 500, 600 and 700. Bias layers 410, 510, 610 and 710 are configured to induce a uniform pinning or biasing field across free layers 408, 508, 608 and 708, respectively. First bias layers 410, 510, 610 and 710 can be antiferromagnetic layers. Example antiferromagnetic bias materials include, but are not limited to, iridium manganese (IrMn), platinum manganese (PtMn), nickel manganese (NiMn), rhodium manganese (RhMn) and ruthenium rhodium manganese (RuRhMn). The second bias layers 416, 516, 616 and 716 are illustrated as being formed on opposing sides of the active region of each sensor stack and placed outside of insulating material 414, 514, 614 and 714. However, the second bias layers 416, 516, 616 and 716 can be formed on opposing sides of at least free layers 408, 508, 608 and 708 of each sensor 400, 500, 600 and 700. Second bias layers 416, 516, 616 and 716 can be configured to bias free layers 408, 508, 608 and 708 at edges (i.e. sides 411, 511, 611, 711, 413, 513, 613 and 713) of the free layers to eliminate domain edges and at the same time leave a small field at the center of the free layers. The second bias layers 416, 516, 616 and 716 can be made of a hard ferromagnetic material. Example second bias layer materials include, but are not limited to, cobalt iron chromium (CoFeCr), cobalt chromium platinum (CoCrPt) and cobalt platinum (CoPt).

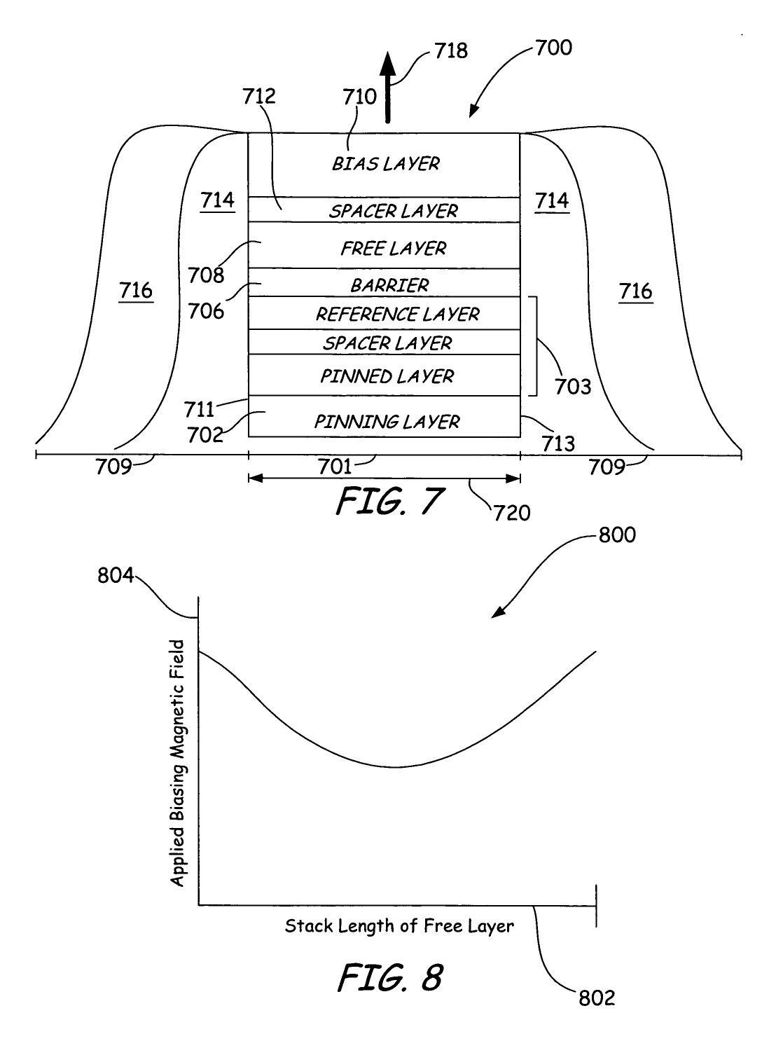

FIG. 8 illustrates a magnetic profile 800 of a free layer of a tunneling giant magnetoresistance sensor in accordance with the present invention. Magnetic profile 800 represents the profiles of tunneling giant magnetoresistance sensors 400, 500, 600 and 700. Axis 802 of magnetic profile 800 represents stack length 420, 520, 620 and 720. Axis 804 of magnetic profile 800 represents the biasing magnetic field applied to the free layer by both second bias layers 416, 516, 616 and 716 and first bias layers 410, 510, 610 and 710. Magnetic profile 800 shows that the combination of the first and second applied bias layers allows the ends of the free layer to be susceptible to a stronger magnetic field than at the center of the free layer. The center of the free layer is able to rotate and therefore generate a large sensing output as well as applies a more intense biasing magnetic field compared to the biasing field applied in profile 200 of FIG. 2. In addition, the combination of the first and second bias layers applies a non-uniform biasing magnetic field compared to the uniform biasing field applied in profile 300 of FIG. 3.

Sensors 400, 500, 600 and 700 have a variety of common stack layers in their respective active regions 401, 501, 601 and 701. These layers include barrier layer 406, 506, 606 and 706 and free layers 408, 508, 608 and 708. Sensors 400, 500 and 700 all have common pinning layers 402, 502 and 702. Barrier layers 406, 506, 606 and 706 can be made of magnesium oxide (MgO) and aluminum oxide (Al₂O₃). However, other materials with similar properties are possible. Free layers 408, 508, 608 and 708 can be made of nickel iron (NiFe) and cobalt iron (CoFe). However, other materials with similar properties are possible. Pinning layers 402, 502 and 702 can be made of antiferromagnetic materials, such as PtMn, IrMn and NiMn, and hard magnetic materials, such as CoPt and CoCrPt. However, other materials having similar properties are possible.

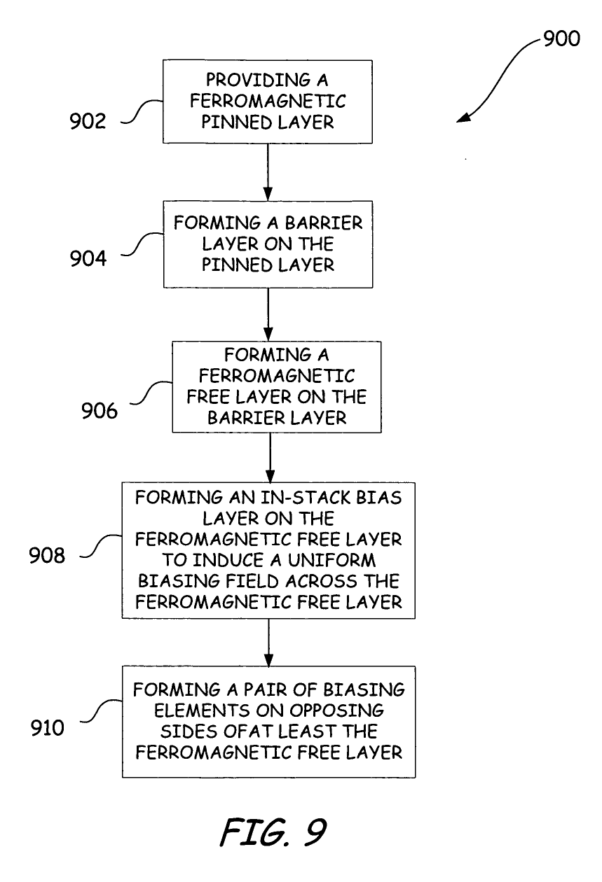

FIG. 9 illustrates a method 900 of fabricating a TGMR sensor in accordance with embodiments of the present invention. As illustrated at block 902, a pinned layer is provided. At block 904, a barrier layer is formed on the pinned layer. At block 906, a free layer is formed on the barrier layer. At block 908, a first bias layer is formed on the free layer to induce a uniform biasing field across the free layer. At block 910, a second bias layer is formed on opposing sides of at least the free layer of the tunneling giant magnetoresistance sensor.

The steps illustrated in FIG. 9 are known as a process of forming a bottom type sensor. These steps can be varied so as to fabricate a top type sensor as well. Also, the steps should be performed based on the embodiments of the invention that are illustrated and described with respect to FIGS. 4-7. For example additional steps can be added, such as providing a pinning layer of which the pinned layer can be provided on, providing a synthetic antiferromagnet of which the pinned layer is a portion thereof, forming a spacer layer that is positioned between the free layer and the first bias layer and adjusting a thickness of the spacer layer to vary a bias strength applied by the first bias layer on the free layer. It should be noted that the steps can be performed in the order necessary to fabricate different types of and additional steps can be added as needed.

It is to be understood that even though numerous characteristics and advantages of various embodiments of the invention have been set forth in the foregoing description, together with details of the structure and function of various embodiments of the invention, this disclosure is illustrative only, and changes may be made in detail, especially in matters of structure and arrangement of parts within the principles of the present invention to the full extent indicated by the broad general meaning of the terms in which the appended claims are expressed. For example, the particular elements may vary depending on the particular application while maintaining substantially the same functionality without departing from the scope and spirit of the present invention. In addition, although the preferred embodiment described herein is directed to a data storage system, it will be appreciated by those skilled in the art that the teachings of the present invention can be applied to other types of systems, without departing from the scope and spirit of the present invention.

What is claimed is:

1. A tunneling giant magnetoresistance sensor comprising:
a pinned layer;
a free layer positioned on the pinned layer;
a barrier layer positioned between the pinned layer and the free layer;
a first bias layer positioned on the free layer and configured to induce a uniform biasing field across the free layer; and
a second bias layer positioned on opposing sides of at least the free layer of the tunneling giant magnetoresistive sensor, wherein the second bias layer cooperates to apply a biasing field at edges of the opposing sides of at least the free layer.

2. The tunneling giant magnetoresistance sensor of claims 1, wherein the barrier layer comprises one of a magnesium oxide and an aluminum oxide.

3. The tunneling giant magnetoresistance sensor of claim 1, further comprising an insulating layer positioned on opposing sides of the tunneling giant magnetoresistance sensor between edges of the sensor and the second bias layer.

4. The tunneling giant magnetoresistance sensor of claim 1, wherein the second bias layer comprises a pair of permanent magnets made of a hard ferromagnetic material.

5. The tunneling giant magnetoresistance sensor of claim 1, wherein the pinned layer is a portion of a synthetic antiferromagnet.

6. The tunneling giant magnetoresistance sensor of claim 1, further comprising a pinning layer, wherein the pinning layer is adjacent the pinned layer.

7. The tunneling giant magnetoresistance sensor of claim 1, further comprising a spacer layer positioned between the free layer and the first bias layer, wherein a thickness of the spacer layer is adjustable for varying a bias strength applied by the first bias layer on the free layer.

8. The tunneling giant magnetoresistance sensor of claim 1, wherein the first bias layer comprises an antiferromagnetic material.

9. The tunneling giant magnetoresistance sensor of claim 1, wherein the free layer comprises a multilayered stack of ferromagnetic materials.

10. A sensor comprising:
an active region, wherein the active region includes a first bias layer; and
a passive region, wherein the passive region includes an insulating layer and a second bias layer, further wherein the insulating layer is positioned between the active region and the second bias layer.

11. The sensor of claim 10, wherein the first bias layer comprises an antiferromagnetic material.

12. The sensor of claim 10, wherein the active region includes a synthetic antiferromagnet comprising:
a pinned layer;
a reference layer formed on the pinned layer; and
a spacer layer positioned between and the pinned layer and the reference layer.

13. The sensor of claim 10, wherein the active region further comprises:
an pinning layer; and
a pinned layer, wherein the pinned layer is formed on the pinning layer.

14. The sensor of claim 10, wherein the active region further comprises:
a free layer; and
a spacer layer positioned between the free layer and the first bias layer, wherein a thickness of the spacer layer is adjustable for varying a bias strength applied by the first bias layer on the free layer.

15. The sensor of claim 14, wherein the first bias layer comprises an antiferromagnetic material.

16. The sensor of claim 10, wherein the second bias layer comprises a pair of permanent magnets made of a hard ferromagnetic material.

17. A sensor comprising:
a sensor stack having a first side and a second side, wherein the sensor stack includes a first bias layer;
a second bias layer positioned proximate the first side of the sensor stack; and
a third bias layer positioned proximate to the second side of the sensor stack.

18. The method of claim 17, wherein the sensor stack further comprises:
a synthetic antiferromagnet of which a pinned layer is a portion thereof;
a barrier layer positioned on the synthetic antiferromagnet; and
a free layer positioned on the barrier layer.

19. The method of claim 18, wherein the sensor stack further comprises a pinning layer, wherein the synthetic antiferromagnet is positioned on the pinning layer.

20. The method of claim 18, wherein the sensor stack further comprises a spacer layer that is positioned between the free layer and the first bias layer, wherein a thickness of the spacer layer is adjusted to vary a bias strength applied by the first bias layer on the free layer.
